(19) United States
(12) Patent Application Publication
(10) Pub. No.: US 2023/0082220 A1
(43) Pub. Date: Mar. 16, 2023

(54) CHARGING SYSTEM

(71) Applicant: TOYOTA JIDOSHA KABUSHIKI KAISHA, Toyota-shi (JP)

(72) Inventor: Hiroyuki ISHIHARA, Toyota-shi (JP)

(73) Assignee: TOYOTA JIDOSHA KABUSHIKI KAISHA, Toyota-shi (JP)

(21) Appl. No.: 17/879,883

(22) Filed: Aug. 3, 2022

(30) Foreign Application Priority Data
Sep. 15, 2021 (JP) 2021-150251

(51) Int. Cl. B60L 53/12; B60L 53/65; B60L 53/66; G01R 31/08

(52) U.S. Cl. CPC B60L 53/12; B60L 53/65; B60L 53/66; G01R 31/08

(57) ABSTRACT

A charging system includes a charging device including a plurality of power supply segments and a management device. Each of the plurality of power supply segments is configured to supply charging power to an electrified vehicle in proximity to the power supply segment in a non-contact manner. The management device is configured to manage the charging device and communicate with the electrified vehicle. The management device is configured to, when the electrified vehicle detects an abnormality in power supply from the power supply segment, regarding any of the plurality of power supply segments, receive an abnormality signal including identification information corresponding to the power supply segment from the electrified vehicle. The management device is configured to, when receiving the abnormality signal from a plurality of the electrified vehicles regarding any of the plurality of power supply segments, determine that there is an abnormality in the power supply segment.

### CROSS-REFERENCE TO RELATED APPLICATION

This application claims priority to Japanese Patent Application No. 2021-150251 filed on Sep. 15, 2021, incorporated herein by reference in its entirety.

### BACKGROUND

### 1. Technical Field

The technique of the present disclosure relates to a charging system for an electrified vehicle.

### 2. Description of Related Art

Japanese Unexamined Patent Application Publication No. 2020-178471 (JP 2020-178471 A) discloses a non-contact power supply system including a traveling power supply system on a road side and a traveling power receiving system on a vehicle side. The traveling power supply system includes a plurality of power supply segments. The power supply segments each include an electrical characteristic acquisition unit and an abnormality determination unit. The electrical characteristic acquisition unit acquires a current and a voltage (hereinafter referred to as “electrical characteristics”) of each circuit in the segment involved in power supply. The abnormality determination unit determines whether the electrical characteristics of the segment show abnormal values, using the acquired electrical characteristics.

### SUMMARY

In the technique of JP 2020-178471 A, it is necessary to provide the electric characteristic acquisition unit and the abnormality determination unit in each of the power supply segments, in order to determine whether there is an abnormality in the power supply segment. The present disclosure provides a charging system capable of determining whether there is an abnormality in a charging device at low cost.

In a first aspect of the present disclosure, a charging system includes a charging device including a plurality of power supply segments and a management device. Each of the plurality of power supply segments is configured to supply charging power to an electrified vehicle in proximity to the power supply segment in a non-contact manner. The management device is configured to manage the charging device. The management device is configured to communicate with the electrified vehicle. The management device is configured to, when the electrified vehicle detects an abnormality in power supply from the power supply segment, regarding any of the plurality of power supply segments, receive an abnormality signal including identification information corresponding to the power supply segment from the electrified vehicle. The management device is configured to, when the management device receives the abnormality signal from a plurality of the electrified vehicles regarding any of the plurality of power supply segments, determine that there is an abnormality in the power supply segment.

With the above configuration, regarding any of the plurality of power supply segments, when the electrified vehicle detects an abnormality in power supply from the power supply segment, the management device receives an abnormality signal including identification information corresponding to the power supply segment. When receiving the abnormality signal including identification information from a plurality of the electrified vehicles regarding any of the plurality of power supply segments, the management device determines that there is an abnormality in the power supply segment. As described above, in the charging system, it is possible to determine whether there is an abnormality in the power supply segment, without providing an abnormality determination device (for example, a sensor) for each power supply segment in order to determine whether there is an abnormality in the power supply segment. That is, it is not necessary to provide an abnormality determination device for each power supply segment. Therefore, it is possible to perform determination on whether there is an abnormality in the power supply segment at low cost.

It is conceivable that the electrified vehicle detects an abnormality in power supply from the power supply segment when there is an abnormality in the electrified vehicle itself, in addition to the case where there is an abnormality in the power supply segment. Thus, it is difficult to determine whether the electrified vehicle or the power supply segment has an abnormality when the abnormality signal is received from only one electrified vehicle. In this regard, with the above configuration, when receiving an abnormality signal from a plurality of the electrified vehicles regarding any one of the plurality of power supply segments, the management device determines that there is an abnormality in the power supply segment. Therefore, the reliability of the determination can be increased.

In the charging system according to the first aspect of the present disclosure, the electrified vehicle may be configured to transmit the abnormality signal to the management device when a difference between a required power required of the power supply segment and a received power received from the power supply segment is equal to or more than a predetermined value.

In the charging system according to the first aspect of the present disclosure, the electrified vehicle may be configured to transmit the abnormality signal to the management device when electric power is not received from the power supply segment.

When a difference between a required power of the power supply segment and a received power from the power supply segment is equal to or more than a predetermined value, or when electric power is not received from the power supply segment, it is highly likely that there is an abnormality in at least one of the electrified vehicle and the power supply segment. With the above configuration, the electrified vehicle can transmit the abnormality signal to the management device when it is highly likely that there is an abnormality in at least one of the electrified vehicle and the power supply segment.

In the charging system according to the first aspect of the present disclosure, the identification information may be position information corresponding to a position in which the power supply segment is disposed.

In the charging system according to the first aspect of the present disclosure, the position information may be information indicating a position of the electrified vehicle at a time when the electrified vehicle detects the abnormality in power supply from the power supply segment. With the above configuration, the management device that has received the abnormality signal can appropriately identify the power supply segment in which there can be an abnormality, using the position information.

In the charging system according to the first aspect of the present disclosure, the identification information may be unique information uniquely assigned to each of the plurality of power supply segments. With the above configuration, the management device that has received the abnormality signal can appropriately identify the power supply segment in which there can be an abnormality, using the unique information.

In the charging system according to the first aspect of the present disclosure, the plurality of power supply segments may be disposed along a route on which the electrified vehicle travels.

In the charging system according to the first aspect of the present disclosure the plurality of power supply segments may represent a coil embedded in a road surface on which the electrified vehicle travels. With the above configuration, when the electrified vehicle approaches the coil embedded in the road surface during traveling, the electrified vehicle can be supplied with charging power from the coil. Thus, the electrified vehicle can be supplied with charging power from the coil during traveling.

### BRIEF DESCRIPTION OF THE DRAWINGS

Features, advantages, and technical and industrial significance of exemplary embodiments of the present disclosure will be described below with reference to the accompanying drawings, in which like signs denote like elements, and wherein:

FIG. 1 shows an outline of a charging system;

FIG. 2 shows a schematic circuit diagram of an electrified vehicle and a charging device;

FIG. 3 shows a flowchart of a process executed by the electrified vehicle; and

FIG. 4 shows a flowchart of a process executed by the management device.

### DETAILED DESCRIPTION OF EMBODIMENTS

### First Embodiment

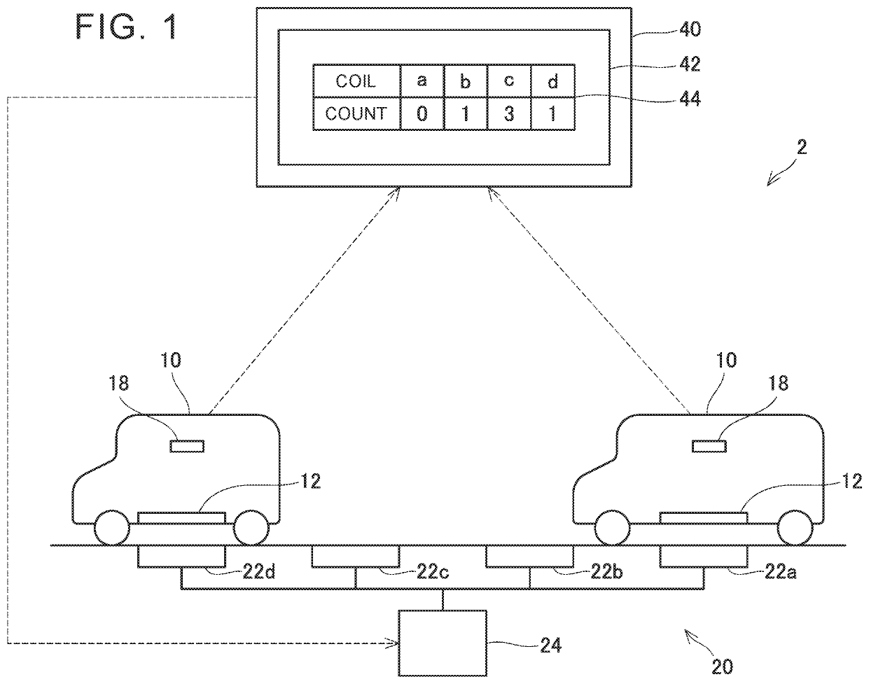

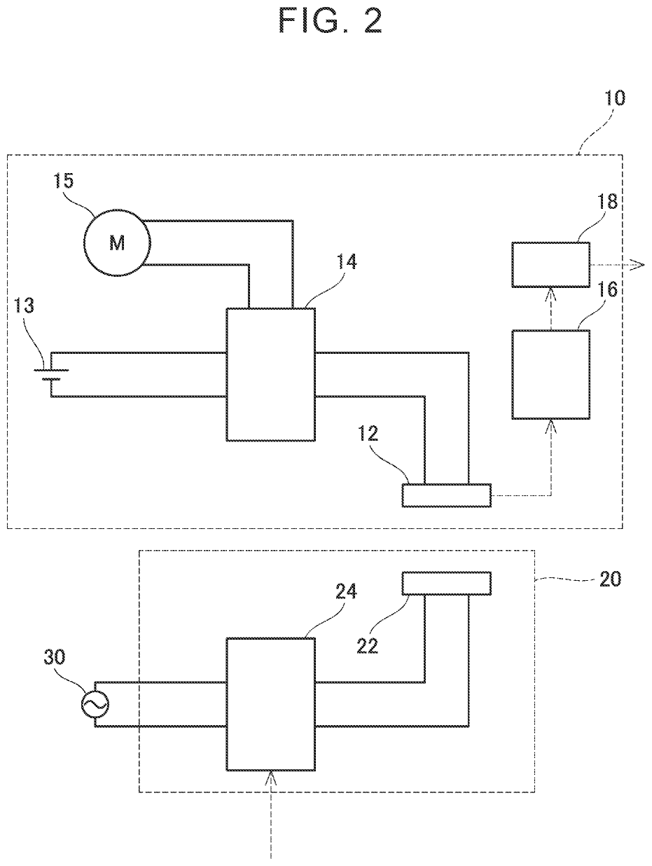

A charging system 2 of a first embodiment will be described with reference to the drawings. The charging system 2 of the present embodiment is a system for charging a plurality of electrified vehicles 10 traveling on a road surface. As shown in FIG. 1, the charging system 2 includes a charging device 20 and a management device 40. The charging device 20 includes multiple road surface-side coils 22a to 22d arranged at regular intervals. In the following, when the road surface-side coils 22a to 22d are not particularly distinguished from each other, they will be simply referred to as “road surface-side coils 22” (see FIG. 2). The road surface-side coils 22 are embedded in the road surface on which the electrified vehicles 10 travel. Although the four road surface-side coils 22a to 22d are shown in the drawing, the number of the road surface-side coils 22 may be less than four or five or more. Further, the intervals at which the road surface-side coils 22 are arranged do not have to be regular intervals.

When the electrified vehicles 10 travel on the road surface in which the road surface-side coils 22 are embedded, the charging device 20 supplies charging power to the electrified vehicles 10 in a non-contact manner. Specifically, when the electrified vehicles 10 travel on the road surface, the electrified vehicles 10 each approach the road surface-side coils 22a to 22d in succession. When the electrified vehicle 10 comes in proximity, each of the road surface-side coils 22a to 22d supplies charging power to the electrified vehicle 10 in a non-contact manner. That is, charging power is supplied to the electrified vehicle 10 from the road surface-side coils 22a to 22d in this order.

The electrified vehicle 10 is a vehicle that can travel using electricity as a power source, such as a battery electric vehicle and a hybrid electric vehicle. As shown in FIGS. 1 and 2, the electrified vehicle 10 includes a vehicle-side coil 12, a battery 13, a power conversion device 14, a traction motor 15, a controller 16, and a communication interface 18.

The battery 13 is connected to the motor 15 via the power conversion device 14. Direct-current (DC) power output from the battery 13 is converted into alternating-current (AC) power by the power conversion device 14 and supplied to the motor 15. The motor 15 drives the wheels of the electrified vehicle 10, so that the electrified vehicle 10 travels. The power conversion device 14 can also convert the electric power (regenerative power) generated by the motor 15 and supply the converted electric power to the battery 13.

The battery 13 is a secondary battery such as a lithium ion battery. An output voltage of the battery 13 is, for example, 200 volts. The power conversion device 14 includes a voltage converter circuit (not shown), an inverter circuit, and the like. Since the operation of the power conversion device 14 including the voltage converter circuit, the inverter circuit, and the like is well known, detailed description thereof will be omitted. The motor 15 is, for example, a three-phase AC motor.

The vehicle-side coil 12 is connected to the battery 13 via the power conversion device 14. When the electrified vehicle 10 (vehicle-side coil 12) comes in proximity to each road surface-side coil 22, the vehicle-side coil 12 receives charging power from the road surface-side coil 22. Specifically, AC power flows through the road surface-side coil 22, and when the electrified vehicle 10 comes in proximity to the road surface-side coil 22, the AC power also flows through the vehicle-side coil 12 due to magnetic resonance. That is, charging power is supplied from the road surface-side coil 22 to the vehicle-side coil 12 in a non-contact manner. The charging power is converted by the power conversion device 14 and supplied to the battery 13, so that the battery 13 is charged. The method of supplying charging power from the road surface-side coil 22 to the vehicle-side coil 12 in a non-contact manner is not limited to the above magnetic resonance. For example, charging power may be supplied from the road surface-side coil 22 to the vehicle-side coil 12 in a non-contact manner by electromagnetic induction.

The controller 16 calculates a required power required of each road surface-side coil 22 when the electrified vehicle 10 travels on the road surface. The required power may be calculated based on, for example, the output voltage of the battery 13, or may be stored in the controller 16 in advance. The electrified vehicle 10 may include a voltmeter that measures the output voltage of the battery 13. Alternatively, the power conversion device 14 may include a voltmeter. The required power is transmitted to the management device 40 via the communication interface 18. The controller 16 acquires, from the vehicle-side coil 12, a received power received by the vehicle-side coil 12 from the road surface-side coil 22. Then, the controller 16 calculates a difference between the required power and the received power. The difference is used to detect whether there is an abnormality in power supply from the road surface-side coil 22.

Further, the electrified vehicle 10 is configured to be able to communicate with the management device 40 via the communication interface 18. In particular, when the electrified vehicle 10 detects an abnormality in power supply from the road surface-side coil 22, the electrified vehicle 10 transmits an abnormality signal to the management device 40 via the communication interface 18.

The charging device 20 further includes a power transmission circuit 24. The power transmission circuit 24 is a circuit for supplying the road surface-side coil 22 with electric power for supplying charging power to the electrified vehicle 10. As shown in FIG. 2, the power transmission circuit 24 is connected to an external AC power source 30. Although not shown, the power transmission circuit 24 includes a converter circuit that converts AC power supplied from the AC power source 30 into DC power, a step-down converter circuit that steps down the converted DC power, and an inverter circuit that converts the stepped-down DC power into AC power of a desired frequency. The above inverter circuit is provided for each road surface-side coil 22. That is, the power transmission circuit 24 converts AC power supplied from the external AC power source 30 and supplies the converted AC power of a desired frequency to the road surface-side coil 22.

The external AC power source 30 herein may be, for example, a commercial AC power source (electric power system provided by a general power transmission and distribution business operator), or may be a power generation device using wind power or other renewable energy. Alternatively, the charging device 20 may receive power supply from an external DC power source instead of the external AC power source 30. Examples of the DC power source include a solar power generation system and a fuel cell system.

Further, the power transmission circuit 24 is configured to be able to communicate with the management device 40. The power transmission circuit 24 receives, from the management device 40, the required power received by the management device 40 from the electrified vehicle 10. Then, the power transmission circuit 24 converts electric power supplied from the external AC power source 30 based on the required power received from the management device 40, and supplies the converted power to the road surface-side coil 22.

The management device 40 manages the charging device 20 and is configured to be able to communicate with the electrified vehicle 10. The management device 40 includes a controller 42. The controller 42 stores a table 44.

The table 44 is a table for counting the number of times an abnormality signal is received from each road surface-side coil 22, regarding the road surface-side coils 22a to 22d. A coil “a” in the table 44 corresponds to the road surface-side coil 22a in FIG. 1. Similarly, coils “b”, “c”, and “d” in the table 44 correspond to the road surface-side coils 22b, 22c, and 22d in FIG. 1, respectively.

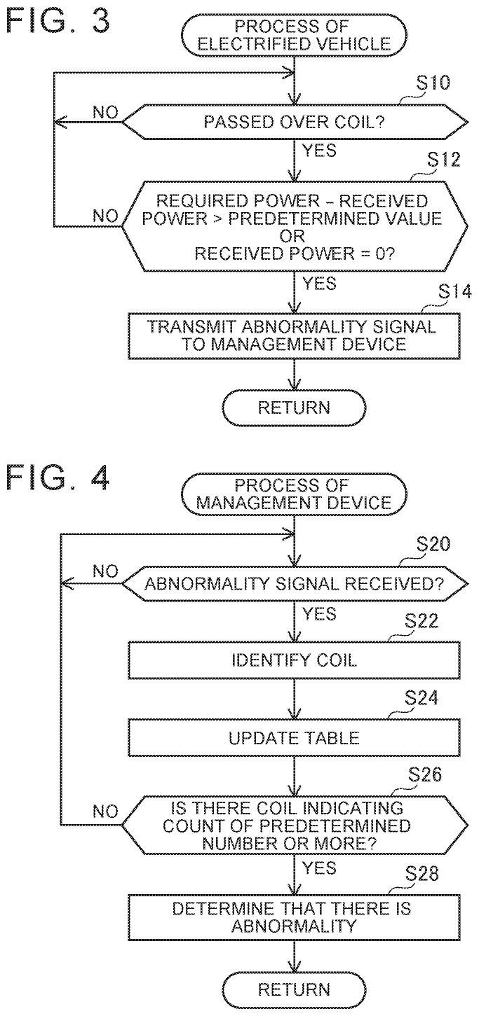

Next, a process executed by the electrified vehicle 10 will be described with reference to FIG. 3. The process of FIG. 3 is executed by the controller 16 of the electrified vehicle 10 while the electrified vehicle 10 is traveling. In the following, for ease of understanding, description will be made with the electrified vehicle 10 serving as the subject, rather than with the controller 16 serving as the subject. The electrified vehicle 10 starts the process of FIG. 3 at a predetermined timing.

In step S10, the electrified vehicle 10 monitors that the electrified vehicle 10 passes over the road surface-side coil 22. For example, the electrified vehicle 10 stores the position of the road surface-side coil 22 (for example, a combination of longitude and latitude). When the electrified vehicle 10 determines that it has passed over the stored position of the road surface-side coil 22, the electrified vehicle 10 determines YES in step S10, and proceeds to step S12. The process of monitoring the passage of the electrified vehicle 10 over the road surface-side coil 22 is not limited to the above mode. For example, the road surface-side coil 22 may be configured to transmit to the electrified vehicle 10 a signal indicating the passage when the electrified vehicle 10 passes over the road surface-side coil 22. When the electrified vehicle 10 receives the signal from the road surface-side coil 22, the electrified vehicle 10 may determine YES in step S10. When the electrified vehicle 10 determines NO in step S10, the process repeats step S10.

In step S12, the electrified vehicle 10 determines whether the difference between the required power and the received power is equal to or more than a predetermined value, or whether the received power is zero. When the electrified vehicle 10 determines that at least one of the above conditions is satisfied (YES in step S12), the process proceeds to step S14. The case where the difference between the required power and the received power is equal to or more than the predetermined value or the case where the received power is zero is a case where there is an abnormality in power supply from the road surface-side coil 22 that the electrified vehicle 10 passed over in step S10 That is, the electrified vehicle 10 determines whether the difference between the required power and the received power is equal to or more than the predetermined value or whether the received power is zero, so as to detect an abnormality in power supply from the road surface-side coil 22 that the electrified vehicle 10 passed over in step S10. When none of the above conditions is satisfied, the electrified vehicle 10 returns to the monitoring process in step S10.

In step S14, the electrified vehicle 10 transmits an abnormality signal to the management device 40 via the communication interface 18. The abnormality signal includes vehicle position information indicating the position (for example, a combination of longitude and latitude) of the electrified vehicle 10 at the time when the electrified vehicle 10 passed over the road surface-side coil 22 in step S10. When the process of step S14 is completed, the process returns to the monitoring process of step S10.

Next, a process executed by the management device 40 will be described with reference to FIG. 4. The management device 40 starts the process of FIG. 4 at a predetermined timing. In step S20, the management device 40 monitors reception of the abnormality signal (see step S14 in FIG. 3) from the electrified vehicle 10. When the management device 40 receives the abnormality signal from the electrified vehicle 10, the management device 40 determines YES in step S20 and the process proceeds to step S22. When the management device 40 does not receive the abnormality signal from the electrified vehicle 10, the management device 40 determines NO in step S20 and the process repeats step S20.

In step S22, the management device 40 identifies one road surface-side coil (abnormal road surface coil) 22. Specifically, the management device 40 stores coil position information indicating a position in which each road surface-side coil 22 of the charging device 20 is disposed (for example, a combination of longitude and latitude). The management device 40 identifies a road surface-side coil 22 disposed closest to the position indicated by the vehicle position information included in the received abnormality signal, among the road surface-side coils 22 indicated by the stored coil position information, as the one road surface-side coil (abnormal road surface coil) 22.

In step S24, the management device 40 updates the table 44 (see FIG. 1). Specifically, the management device 40 increments, by one, the count corresponding to the road surface-side coil (abnormal road surface coil) 22 identified in step S22. For example, when the road surface-side coil 22c is identified as the one road surface-side coil (abnormal road surface coil) 22 in step S22, the management device 40 increments, by one, the count stored in association with the coil “c” corresponding to the road surface-side coil 22c in the table 44. The initial value of the count may be “zero”.

In step S26, the management device 40 determines whether there is a coil for which the count of a predetermined number or more is stored in the table 44. In the present embodiment, the predetermined number is set to “three”. In a modification, the predetermined number may be “two”, or “four” or more. In the present embodiment, the count corresponding to the coil “c” in the table 44 (see FIG. 1) indicates “three”. Therefore, the management device 40 determines YES in step S26, and the process proceeds to step S28. When the management device 40 determines that there is no coil for which the count of the predetermined number or more is stored (NO in step S26), the management device 40 returns to the process of step S20.

In step S28, the management device 40 determines that there is an abnormality in the road surface-side coil 22 identified in step S26 (road surface-side coil 22c in the present embodiment). In this case, the management device 40 notifies an administrator of, for example, the road surface-side coil 22 that has been determined to have an abnormality. As a result, the operator who has been notified by the administrator can maintain the road surface-side coil 22 that has been determined to have an abnormality.

According to the above configuration, when, regarding each of the road surface-side coils 22, the electrified vehicle 10 detects an abnormality in power supply from the road surface-side coil 22, the electrified vehicle 10 transmits to the management device 40 the abnormality signal including the vehicle position information indicating the position of the electrified vehicle 10 at the time when the electrified vehicle 10 passed over the road surface-side coil 22 (step S14 in FIG. 3). When the management device 40 receives the abnormality signal including the vehicle position information from a plurality of electrified vehicles 10 regarding any of the road surface side coils 22, the management device 40 determines that there is an abnormality in the road surface-side coil 22 (step S28 in FIG. 4). Thus, in the charging system 2, it is possible to determine whether there is an abnormality in the road surface-side coil 22 without providing an abnormality determination device (for example, a sensor) for each of the road surface-side coils 22 in order to determine whether there is an abnormality in the road surface-side coil 22. That is, it is not necessary to provide an abnormality determination device for each road surface-side coil 22. Therefore, it is possible to perform determination on whether there is an abnormality in the road surface-side coil 22 at low cost.

It is conceivable that the electrified vehicle 10 detects an abnormality in power supply from the road surface-side coil 22 when there is an abnormality in the electrified vehicle 10 itself, in addition to the case where there is an abnormality in the road surface-side coil 22. Thus, it is difficult to determine whether the electrified vehicle 10 or the road surface-side coil 22 has an abnormality, when the abnormality signal is received from only one electrified vehicle 10. In contrast, with the above configuration, the management device 40 determines that there is an abnormality in the road surface-side coil 22 when the management device 40 receives the abnormality signal from the plurality of electrified vehicles 10 for any of the road surface-side coils 22. Therefore, the reliability of the determination can be improved.

Further, the configuration of the present embodiment is also useful in a configuration in which each road surface-side coil 22 is provided with an abnormality determination device. The abnormality determination device is a device for determining whether there is an abnormality in the power transmission circuit 24, and may include, for example, a current sensor, a voltage sensor, and the like. For example, as a situation in which an abnormality is detected in power supply from the road surface-side coil 22, a situation is assumed in which metal foreign matter is present above the road surface-side coil 22 (between the road surface side coil 22 and the electrified vehicle 10). In this case, since there is no abnormality in the power transmission circuit 24 of the road surface-side coil 22, the abnormality determination device does not determine the abnormality in the road surface-side coil 22. However, since the magnetic field received by the vehicle-side coil 12 from the road surface-side coil 22 is weakened by the metal foreign matter, the received power received by the vehicle-side coil 12 is reduced. In this case, the electrified vehicle 10 transmits the abnormality signal to the management device 40. When the management device 40 receives the abnormality signal from the plurality of electrified vehicles 10 for the road surface-side coil 22, the management device 40 can determine that there is a charging abnormality despite that there is no abnormality in the road surface-side coil 22. That is, the management device 40 can specify that the cause of the charging abnormality is not the abnormality in the road surface-side coil 22 but can be the presence of the metal foreign matter, for example.

The technique of the present disclosure and the correspondence in the above embodiment in which the technique is carried out will be described. The road surface-side coil 22 in the present embodiment is an example of a “power supply segment” in the present technique. The vehicle position information in the present embodiment is an example of “identification information” in the present technique. The vehicle position information is an example of “position information” in particular.

### Second Embodiment

A second embodiment will be described. In the second embodiment, information included in the abnormality signal is different from that in the first embodiment. Further, in the second embodiment, each road surface-side coil 22 is assigned a coil unique number uniquely assigned to the road surface-side coil 22. For example, a coil unique number “1111” is assigned to the road surface-side coil 22a. Similarly, coil unique numbers “2222”. “3333”, and “4444” are assigned to the road surface-side coils 22b, 22c, and 22d, respectively.

When passing over the road surface-side coil 22, the electrified vehicle 10 receives a signal from the road surface-side coil 22 including the coil unique number assigned to the road surface-side coil 22. In step S10 in FIG. 3, when the electrified vehicle 10 receives the signal including the coil unique number, the electrified vehicle 10 determines that the electrified vehicle 10 has passed over the coil. Then, when the electrified vehicle 10 determines YES in step S12, the electrified vehicle 10 transmits the abnormality signal including the coil unique number received from the road surface-side coil 22 to the management device 40 in step S14. In the modification, the electrified vehicle 10 may store the coil unique number assigned to the road surface-side coil 22 in association with the coil position information indicating the position in which the road surface-side coil 22 is disposed. When the electrified vehicle 10 determines YES in step S12, the electrified vehicle 10 may identify the coil unique number assigned to the road surface-side coil 22 based on the coil position information closest to the vehicle position information indicating the position of the electrified vehicle 10 at that time. Then, the electrified vehicle 10 may transmit the abnormality signal including the identified coil unique number to the management device 40.

When the management device 40 receives the abnormality signal including the coil unique number from the electrified vehicle 10 in step S20 in FIG. 4, the management device 40 identifies one road surface-side coil 22 using the coil unique number. Then, in step S24, the management device 40 increments, by one, the count corresponding to the identified road surface-side coil 22. In the table 44 of the second embodiment, instead of the coils “a”, “b”, “c”, and “d”, the coil unique numbers “1111”, “2222”, “3333”, and “4444” may be stored, respectively. The coil unique number is an example of “identification information” in the present technique. The coil unique number is an example of “unique information” in particular.

In the above embodiment, the charging system 2 has been described in which each of the road surface-side coils 22 embedded in the road surface supplies, in a non-contact manner, charging power to the electrified vehicle 10 that is in proximity to the road surface-side coil 22, while the electrified vehicle 10 is traveling. In the modification, the charging system 2 is not limited to the charging system in which charging power is supplied in a non-contact manner while the electrified vehicle 10 is traveling, and only needs to have a configuration in which charging power is supplied to the electrified vehicle 10 in a non-contact manner. For example, a configuration may be adopted in which a coil is embedded in a parking lot where the electrified vehicle 10 can be parked and charging power may be supplied to the electrified vehicle 10 in a non-contact manner while the electrified vehicle 10 is parked in the parking lot (that is, the electrified vehicle 10 is stopped). In this modification, the coil embedded in the parking lot is an example of the “power supply segment” in the present technique.

Although the specific examples of the present disclosure have been described in detail above, these are merely examples and do not limit the scope of claims. The techniques described in the claims include various modifications and alternations of the specific examples illustrated above. The technical elements described in the present specification or drawings exhibit technical usefulness alone or in various combinations, and are not limited to the combinations described in the claims at the time of filing. In addition, the techniques illustrated in the present specification or drawings can achieve a plurality of objectives at the same time, and achieving one of the objectives itself has technical usefulness.

What is claimed is:

1. A charging system comprising:
a charging device including a plurality of power supply segments, each of the plurality of power supply segments being configured to supply charging power to an electrified vehicle in proximity to the power supply segment in a non-contact manner; and
a management device configured to
manage the charging device,
communicate with the electrified vehicle,
when the electrified vehicle detects an abnormality in power supply from the power supply segment, regarding any of the plurality of power supply segments, receive an abnormality signal including identification information corresponding to the power supply segment from the electrified vehicle, and
when the management device receives the abnormality signal from a plurality of the electrified vehicles regarding any of the plurality of power supply segments, determine that there is an abnormality in the power supply segment.

2. The charging system according to claim 1, wherein the electrified vehicle is configured to transmit the abnormality signal to the management device when a difference between a required power required of the power supply segment and a received power received from the power supply segment is equal to or more than a predetermined value.

3. The charging system according to claim 1, wherein the electrified vehicle is configured to transmit the abnormality signal to the management device when electric power is not received from the power supply segment.

4. The charging system according to claim 1, wherein the identification information is position information corresponding to a position in which the power supply segment is disposed.

5. The charging system according to claim 4, wherein the position information is information indicating a position of the electrified vehicle at a time when the electrified vehicle detects the abnormality in power supply from the power supply segment.

6. The charging system according to claim 1, wherein the identification information is unique information uniquely assigned to each of the plurality of power supply segments.

7. The charging system according to claim 1, wherein the plurality of power supply segments is disposed along a route on which the electrified vehicle travels.

8. The charging system according to claim 7, wherein the plurality of power supply segments represents a coil embedded in a road surface on which the electrified vehicle travels.
